(19) United States
(12) Patent Application Publication
(10) Pub. No.: US 2019/0239342 A1
(43) Pub. Date: Aug. 1, 2019

(54) CIRCUIT BOARD AND DETECTING DEVICE

(71) Applicants: HKC Corporation Limited, Shenzhen, Guangdong (CN); CHONGQING HKC OPTOELECTRONICS TECHNOLOGY CO., LTD., Chongqing (CN)

(72) Inventor: Hong-Hui Chen, Chongqing (CN)

(21) Appl. No.: 16/330,096

(22) PCT Filed: Jun. 27, 2018
(86) PCT No.: PCT/CN2018/093154

§ 371 Date: Mar. 3, 2019

(30) Foreign Application Priority Data
Jul. 12, 2017 (CN) 201720842671.1

(51) Int. Cl. H05K 1/02; H01R 12/72; H01R 13/41; G01R 31/28; G01R 1/067

(52) U.S. Cl. CPC H05K 1/0268; H01R 12/722; H01R 13/41; H05K 2201/10128; G01R 1/06738; H05K 2201/09418; G01R 31/2808

(57) ABSTRACT

The exemplary embodiment of the present disclosure provides a circuit board and a detecting device, the circuit board includes: a substrate; a connector, the connector includes a first side surface and a second side surface opposite to the first side surface, the connector is defined on the substrate with the first side surface is adjacent to an edge of the substrate; a plurality of test points, the test points are defined on the substrate and arranged in a straight line along the second side surface. The detecting is configured to detect the circuit board, the detecting device includes: a fixing table; a detecting probe, the detecting probe is fixed on the fixing table and configured to contract with the test points on the circuit board to transmit a signal.

### FIELD

The present disclosure generally relates to the technical field of display, and more particularly relates to a circuit board and a detecting device for the circuit board.

### BACKGROUND

With the continuous improvement of economy and technology, the electronic products, such as, smart phones with display screens, flat-panel computers, and liquid crystal display televisions, have become more and more popular, meanwhile bringing increasing demands for quality and performances of the display screen of the electronic product. Therefore, manufacturing the display screen which has high quality and performance, such as, high image quality, under-power, no radiation, stable display, and so on, has become an essential competitiveness for occupying the liquid crystal display market.

In order to ensure the manufactured display screen with foregoing high quality and performance, it needs to detect the display screen in the manufacturing process, to verify whether the display panels exist defects. Hence, after the display panel has been manufactured, and before the liquid crystal display panel is packaged, a PCBI detecting would be carried out to the liquid crystal display panel. During the process of the PCBI detecting, it needs to manually insert a signal wire connected to a detector body into a connector of a printed circuit board (PCB), and after the detecting is finished, the signal wire is then manually pulled out from the connector on the circuit board. Currently, almost all of the PCBI detectings are performed using the manually inserting-and-pulling mode. However, the manually inserting-and-pulling mode exists the following defects: time consuming, and labor wasting. Furthermore, manually inserting-and-pulling the signal wire may cause damage to the connector on the circuit board, and further affect the quality of the display product.

In order to solve the problems caused by the manually inserting-and-pulling mode in the detecting process, the inventor of the present disclosure introduced a PCBI automatic detecting device in the PCBI detecting for the display panel, and added test points on the circuit, to transmit test signal by the detecting device connecting the test points on the circuit board to finish the PCBI automatic detecting. However, since the circuit board is defined with the test points, the dimension and cost of the circuit board are increased accordingly. If the customer has a clear requirement for the dimension of the circuit board, the test points cannot be added on the circuit board without increasing the width of the circuit board, thus the PCBI automatic detecting cannot be carried out for the lack of the test points.

Therefore, how to add the test points on the circuit board, and design the positions of the test points and the connector without increasing the dimension of the circuit board, and how to improve the detecting device according to the positions of designed test points and the connector, to allow the detecting device accordant connecting with the test points on the circuit board to transmit the test signal, for carrying out the PCBI automatic detecting, are the technical problems which are necessary to be solved by persons skilled in the art.

### SUMMARY

The present disclosure provides a circuit board and a detecting device for detecting the circuit board, by adding a plurality of test points on the circuit board, and optimizing the design of positions for the test points and the connector, as well as optimizing the detecting device according to the optimized positions of the connector and the test points, allow the test points to contact with the detecting device during detecting to transmit test signal, to perform the PCBI automatic detecting.

In order to achieve the above object, one aspect, the exemplary embodiment of the present disclosure provides a circuit board, which includes: a substrate; a connector, which includes a first side surface and a second side surface opposite to the first side surface, the connector is defined on the substrate with the first side surface is adjacent to an edge of the substrate; and a plurality of test points, which are defined on the substrate and arranged in a straight line along the second side surface, the plurality of test points are configured to contact to a detecting device in a detecting process to transmit signal.

Another aspect, the exemplary embodiment of the present disclosure provides another circuit board, which includes: a substrate; a connector, which includes a first side surface and a second side surface opposite to the first side surface, the connector is defined on the substrate with the first side surface is adjacent to an edge of the substrate; and a plurality of test points, each one of the plurality of test points has the same shape and same size to that of any other one, the test points are defined on the substrate and arranged in a straight line along the second side surface, two sides of the test points define a first component quiet zone and a second component quiet zone respectively, the first component quiet zone is located between the test points and the second side surface, the plurality of test points are configured to contact to a detecting device in a detecting process to transmit signal.

Another aspect, the exemplary embodiment of the present disclosure provides a detecting device, configured to detect circuit boards as described above, the detecting device includes: a fixing table; and a detecting probe, which is fixed on the fixing table, the detecting probe is configured to contact to the test points on the circuit board in the detecting process to transmit the signal.

The exemplary embodiment of the present disclosure defines that the side surface of the connector can be mounted along the edge of the circuit board by improving the position of the connector on the circuit board, and adds a plurality of test points on the circuit board which are mounted along the other side surface of the connector in a straight line. The present disclosure also improve the detecting device according to the positions of the improved connector and the test points on the circuit board, as such the detecting device can match and contract to the improved test points on the circuit board. The circuit board in the exemplary embodiment of the present disclosure is added with multiple test points without increasing the dimension of the circuit board and the production cost, the locations of the connector and the test points are improved to contract with the detecting device to transmit the signal, for realizing the contracting between the detecting device and the test points to transmit the detecting signal, the aim of carrying out the PCBI automatic detecting is achieved, as the problems caused by the manually inserting-and-pulling mode are avoided, the quality of the display screen is improved accordingly, and the cost is reduced.

### BRIEF DESCRIPTION OF THE DRAWINGS

To better illustrate the technical solutions that are reflected in various embodiments according to this disclosure or that are found in the prior art, the accompanying drawings intended for the description of the embodiments herein or for the prior art will now be briefly described, it is evident that the accompanying drawings listed in the following description show merely some embodiments according to this disclosure, and that those having ordinary skill in the art will be able to obtain other drawings based on the arrangements shown in these drawings without making inventive efforts.

FIG. 1 is a structure diagram of the circuit board of the present disclosure according to an exemplary embodiment;

FIG. 2 is a structure diagram of the detecting device of the present disclosure according to an exemplary embodiment;

FIG. 3 is a structure diagram of the circuit board and the circuit board of the present disclosure according to an exemplary embodiment.

### DETAILED DESCRIPTION

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present invention without creative efforts shall fall within the protection scope of the present invention.

It should be understood that the terms used in this specification and claims such as “comprising” and “including” refer to the existence of the described characteristics, steps, operations, elements and/or components, without excluding one or more other characteristics, steps, operations, elements and/or components, or the existence or addition of their sets.

It is also to be understood that, the terms described in the present disclosure are only for description of specific embodiment, rather than limiting the scope of the disclosure. As described in the specification and claims of the present disclosure, “a”, “one” and “this” is used for description of subject including the plural form, unless other situation is clearly defined in the context.

In detail, the display screen can be carried out in various forms. For example, the display screen described in the exemplary embodiment of the present disclosure include, but not limited to, a thin film transistor LCD display, an organic light-emitting diode display, a liquid crystal display, a plasma panel, a cathode ray tube display, etc.

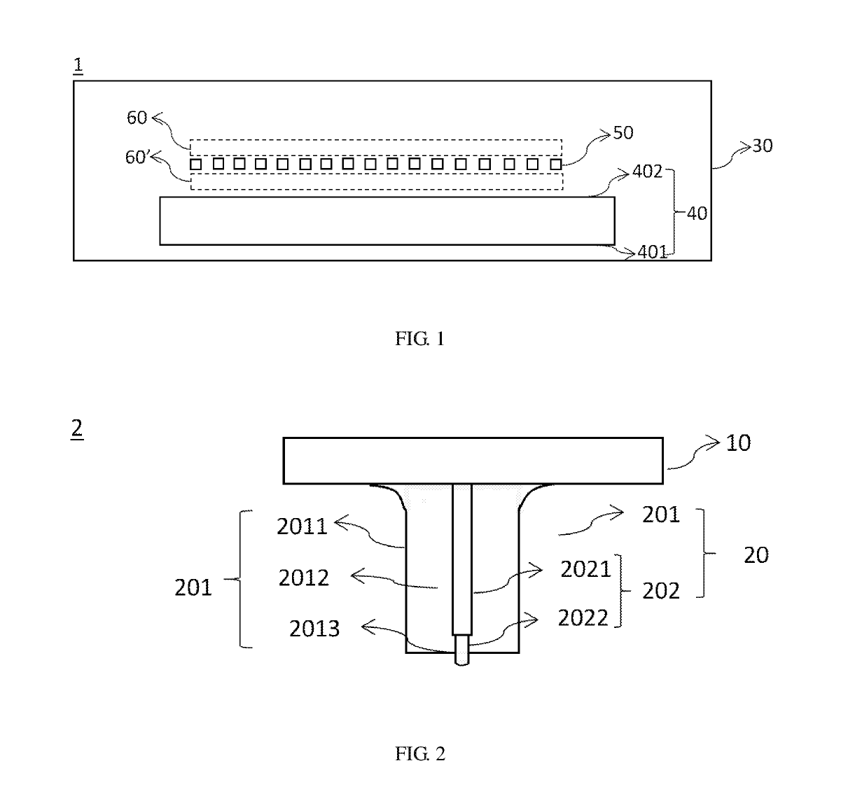

Referring to FIG. 1, FIG. 1 is a structure diagram of the circuit board of the present disclosure according to an exemplary embodiment. In the exemplary embodiment, the circuit board 1 is provided with a substrate 30, a connector 40, a plurality of test points 50, and a first component quiet zone 60, 60′.

The connector 40 includes a first side surface 401 and a second side surface 402 opposite to the first side surface 401, the connector 40 is defined on the substrate 30, the first side surface 401 is adjacent to an edge of the substrate 30.

The test points 50 are defined on the substrate 30 and arranged in a straight line along the second side surface 402, the test points 50 are configured to contact to a detecting device in a detecting process to transmit detecting signal. In some exemplary embodiments, for example, the test points 50 are square shaped, the test point 50 has a length of 0.3 millimeter. In another exemplary embodiment, the test points 50 can have a circular shape, or a rectangle shape, etc. Each one of the plurality of test points 50 has the same shape and same size to that of any other one. Two sides of the test points 50 defines a first component quiet zone 60 and a second component quiet zone 60′ respectively, the first component quiet zone 60 is located between the test points 50 and the second side surface 402 of the connector 40. Electively, the length of the first component quiet zone 60 and the length of the second quiet zone 60′ are both matched to the total length of the plurality of test points 50. Electively, the first component quiet zone 60 has a width of at least 1.15 millimeter, the second component quiet zone 60′ has a width of at least 1.15 millimeter, that is, the area within 1.15 mm from each side of the testing points is not provided with any component by welding.

In the above exemplary embodiment, the position of the connector on the circuit board is modified, and the circuit board is provided with a plurality of test points without increasing the thickness of the circuit board and the production cost. The test points are arranged and mounted in the straight line along the other side of the connector. Two sides of the test points both define a component quiet zone, to prevent the detecting device from contacting with and colliding with other components surrounding the test points to cause interference when the detecting device is contacting with the test points to transmit the detecting signal.

Referring to FIG. 2, FIG. 2 is a structure diagram of the detecting device of the present disclosure according to an exemplary embodiment. In the exemplary embodiment, the testing device 2 is configured to detect the circuit board 1 shown in FIG. 1. The detecting device 2 includes a fixing table 10, and a detecting probe 20. The detecting probe 20 is fixed on the fixing table 10, the detecting probe 20 is configured to contract with the test points 50 on the circuit board 1 in the detecting process to transmit and detect the signal.

The fixing table 10 is located upon the detecting probe 20, and is configured to fix the detecting probe 20. The detecting probe 20 can be fixed on the bottom of the fixing table 20 through multiple methods. Therefore, in multiple exemplary embodiments, the detecting probes 20 can be fixed on the bottom of the fixing table 10 through multiple fixing modes. For example, the fixing mode can be a threaded connecting mode, an electromagnetic adsorption mode, a welding connecting mode, a pivot joint connecting mode, etc.

The detecting probe 20 includes a housing 201 and a probe 202. One end of the detecting probe 20 is fixedly connected with one end of the fixing table 10. The housing 201 includes a body 2011, a cavity 2012 internally formed in the body 2011, and a through hole 2013 formed in the body 2011, the through hole 2013 communicates with the cavity 2012. The probe 202 includes a probe body 2021 and a probe head 2022, the probe body 2021 is located in the cavity 2012 and connected with the fixing table 10, a cross sectional dimension of the probe body 2021 is larger than a dimension of the through hole 2013 to make the probe body 2021 to be limited in the cavity 2012; the probe head 2022 passes through the through hole 2013 and exposes from the housing 201, a cross sectional dimension of the probe head 2022 is matched to the dimension of the through hole 2013. The probe head 2022 can pass through the through hole 2013 and expose from the body 2011, the length of the part of the probe head 2022 which exposes from the body 2011 through passing through the through hole 2013 can be adjusted by horizontally moving the probe 202 along the up-down direction. The probe head 2011 is configured to contact to the test points 50 on the circuit board 1 to transmit the signal, the through hole 2013 is positioned in the center position of the end of the body 2011 away from the fixing table 10, the probe 202 is located at the center position of the body 2011. In some feasible exemplary embodiments, the end of the body 2011 having the probe head 2022 has a length of 1.6 millimeter. One end surface of the body 2011 having the probe head 2022 can be defined as the bottom surface of the body 2011, and the bottom surface faces the test points 50 on the circuit board 1, and a side of the bottom surface perpendicular to the connector 40 has a length of 1.6 millimeter. Two sides of the bottom surface parallel to the connector 40 can be bent upwards to form two vertical surfaces, the heights of the vertical surfaces are both 4.5 millimeter. The two vertical surfaces can be configured to prevent the detecting device 2 from being collided with the connector 40 and the component located at the other end of the second component quiet zone away from the test points 50, when the detecting device 2 is contacting to the test points 50 on the circuit board 1, the disturbance is reduced, as such the accuracy of detecting is improved.

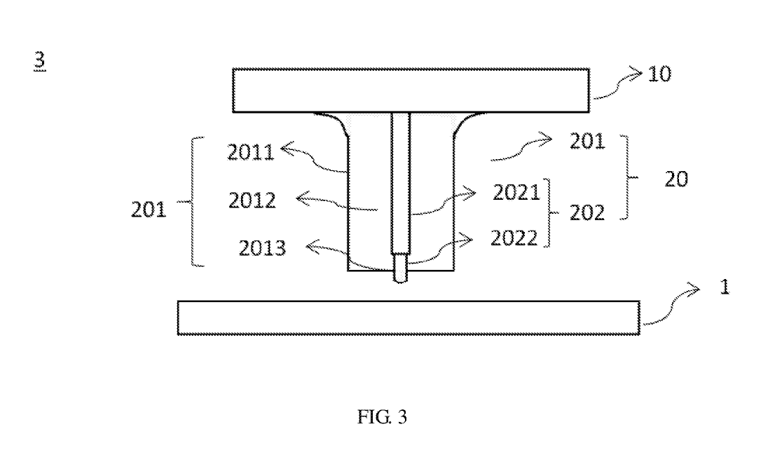

Referring to FIG. 3, which is a structure diagram of the circuit board and the detecting device of the present disclosure according to an exemplary embodiment, in detail, which includes the circuit board 1 and the detecting device 2.

Referring to FIG. 1, the circuit board 1 is provided with the connector 40 and multiple test points 50. The connector 40 includes a first side surface 401 and a second side surface 402 opposite to the first side surface 401, the connector 40 is defined on the substrate 30, the first side surface 401 is adjacent to an edge of the substrate 30. The test points 50 are configured to contract to the detecting device during the detecting process of the circuit board to transmit and detect the signal. Electively, the test points 50 are square shaped, and each test point 50 has a length of 0.3 millimeter. Each one of the plurality of test points 50 has the same shape and same size to that of any other one. Two sides of the test points 50 defines a first component quiet zone 60 and a second component quiet zone 60′ respectively. Selectively, a length of the first component quiet zone 60 and a length of the second component quiet zone 60′ are both matched to the total length of the plurality of test points 50. Electively, the first component quiet zone 60 has a width of at least 1.15 millimeter, the second component quiet zone 60′ has a width of at least 1.15 millimeter, that is, the area within 1.15 mm from each side of the testing points is not provided with any component by welding.

The detecting device 2 is configured to detect the circuit board shown in FIG. 1. The detecting device 2 is provided with a fixing table 10, a detecting probe 20. The fixing table 10 is located upon the detecting probe 20 and configured to fix the detecting probe 20. The detecting probe 20 includes a housing 201 and a probe 202. The housing 201 includes a body 2011, a cavity 2012 internally formed in the body 2011, and a through hole 2013 formed in the body 2011, the through hole 2013 communicates with the cavity 2012. The probe 202 further includes a probe body 2021 and a probe head 2022, a cross sectional dimension of the probe body 2021 is larger than a dimension of the through hole 2013 to make the probe body 2021 to be limited in the cavity 2012; a cross sectional dimension of the probe head 2022 is matched to the dimension of the through hole 2013, as such the probe head 2022 can pass through the through hole 2013 and expose from the housing 201. The length of the part of the probe head 2022 which exposes from the body 2011 through passing through the through hole 2013 can be adjusted by horizontally moving the probe 202 along the up-down direction. The probe head 2011 is configured to contact to the test points 50 on the circuit board 1 to transmit the signal. The probe 202 is located at the center position of the body 2011.

In some feasible exemplary embodiments, the end of the body 2011 having the probe head 2022 has a length of 1.6 millimeter. One end surface of the body 2011 having the probe head 2022 can be defined as the bottom surface of the body 2011, and the bottom surface faces the test points 50 on the circuit board 1, and a side of the bottom surface perpendicular to the connector 40 has a length of 1.6 millimeter. As the detecting device 20 has a deviation in accuracy when the probe 202 contacts to the test points 50 on the circuit board 1, it needs to reserve two spaces at the front and the back of the side edge of the bottom surface of the body 2011 perpendicular to the connector 40, each space has a dimension of 0.5 millimeter. As the length of the side edge of the bottom surface of the detecting probe 20 is 1.6 millimeter, the front and the back of the side edge both need to reserve the space with the dimension of 0.5 millimeter, therefore, the space used for setting the test points 50 on the circuit board 1 has a dimension of 2.6 millimeter. Electively, the length of the test point is 0.3 millimeter, so that, the first component quiet zone 60 and the second component quiet zone 60′ respectively defined at two side of the test points both have the width of at least 1.15 millimeter. Two sides of the bottom surface parallel to the connector 40 can be bent upwards to form two vertical surfaces, the heights of the vertical surfaces are both 4.5 millimeter. The two vertical surfaces can be configured to prevent the detecting device 2 from being collided with the connector 40 and the component located at the other end of the second component quiet zone away from the test points 50, when the detecting device 2 is contacting to the test points 50 on the circuit board 1, the disturbance is reduced, as such the accuracy of detecting is improved.

In the above exemplary embodiments, the position of the connector on the circuit board is modified, and the circuit board is provided with a plurality of test points without increasing the thickness of the circuit board and the production cost. The test points are arranged and mounted in the straight line along the one side of the connector. The the present disclosure also modifies the detecting device according to the position of the test points and the connector on the design circuit board, such the detecting device can be matched and connected with the test points on the modified circuit board. In the exemplary embodiment of the present disclosure, the circuit board is added with multiple test points, the positions of the connector and the test points are also modified, the test points are configured to contract to the detecting device to transmit the signal, as such the detecting device can contact to the test points and transmit the detecting signal to achieve the aim of PCBI automatic detecting, which can avoid that the problem caused by connecting mode of manually inserting and pulling the components together, for improving the quality of the display screen and reducing the cost.

It is to be understood that, the device described in the exemplary embodiments of the present disclosure can be achieved by another means. For example, the above embodiments of the device are merely illustrative. For example, the device is divided according to the structure and function. When the device is implemented, the device can be divided according to another dividing mode. For example, multiple devices or components can be combined or can be integrated into another appliance, or some features can be ignored, or not executed. In addition, the components can be directly coupled with each other, or, coupled or communicated with each other through an interface, a device, or a module. The components can also be electrically or mechanically connected with each other, etc.

The foregoing descriptions are merely specific implementation manners of the present application, but are not intended to limit the protection scope of the present application. Any variation or replacement readily figured out by a person skilled in the art within the technical scope disclosed in the present application shall fall within the protection scope of the present application. Therefore, the protection scope of the present application shall be subject to the protection scope of the claims.

1. A circuit board, comprising:
a substrate;
a connector, comprising a first side surface and a second side surface opposite to the first side surface, the connector being defined on the substrate with the first side surface being adjacent to an edge of the substrate; and
a plurality of test points, defined on the substrate and arranged in a straight line along the second side surface, the plurality of test points being configured to contact to a detecting device in a detecting process to transmit signal.

2. The circuit board according to claim 1, wherein two sides of the test points defines a first component quiet zone and a second component quiet zone respectively, the first component quiet zone is located between the test points and the second side surface.

3. The circuit board according to claim 2, wherein the first component quiet zone has a width of at least 1.15 millimeter.

4. The circuit board according to claim 2, wherein a length of the first component quiet zone is matched to the total length of the plurality of test points.

5. The circuit board according to claim 2, wherein the second component quiet zone has a width of at least 1.15 millimeter.

6. The circuit board according to claim 2, wherein a length of the second component quiet zone is matched to the total length of the plurality of test points.

7. The circuit board according to claim 1, wherein each one of the plurality of test points has the same shape and same size to that of any other one.

8. The circuit board according to claim 1, wherein the test point is square shaped.

9. The circuit board according to claim 1, wherein the test point has a length of side at least 0.3 millimeter.

10. The circuit board according to claim 1, wherein the connector is defined on the substrate, and the first side surface is adjacent to the long edge of the substrate.

11. A circuit board, comprising:
a substrate;
a connector, comprising a first side surface and a second side surface opposite to the first side surface, the connector being defined on the substrate with the first side surface being adjacent to an edge of the substrate; and
a plurality of test points, each one of the plurality of test points having the same shape and same size to that of any other one, the test points being defined on the substrate and arranged in a straight line along the second side surface, two sides of the test points defining a first component quiet zone and a second component quiet zone respectively, the first component quiet zone being located between the test points and the second side surface, the plurality of test points being configured to contact to a detecting device in a detecting process to transmit signal.

12. The circuit board according to claim 11, wherein a length of the first component quiet zone is matched to the total length of the plurality of test points.

13. The circuit board according to claim 11, wherein the first component quiet zone has a width of at least 1.15 millimeter.

14. A detecting device, configured to detect a circuit board, the circuit board comprising:
a substrate;
a connector, comprising a first side surface and a second side surface opposite to the first side surface, the connector being defined on the substrate with the first side surface being adjacent to an edge of the substrate; and
a plurality of test points, defined on the substrate and arranged in a straight line along the second side surface, the plurality of test points being configured to contact to a detecting device in a detecting process to transmit signal,
the detecting device comprising:
a fixing table; and
a detecting probe, fixed on the fixing table, the detecting probe being configured to contact to the test points on the circuit board in the detecting process to transmit the signal.

15. The detecting device according to claim 14, wherein the detecting probe comprises:
a housing, comprising a body connected with the fixing table, a cavity internally formed in the body, and a through hole formed in the body and communicating with the cavity; and
a probe, the probe comprises a probe body and a probe head, the probe body is located in the cavity and connected with the fixing table, the probe head passes through the through hole and exposes from the housing.

16. The detecting device according to claim 15, wherein the through hole is positioned in the center position of the end of the body away from the fixing table.

17. The detecting device according to claim 15, wherein the end of the body having the probe head has a length of 1.6 millimeter.

18. The detecting device according to claim 15, wherein heights of the left and right two sides of the body are both 4.5 millimeter.

19. The detecting device according to claim 15, wherein a cross sectional dimension of the probe body is larger than a dimension of the through hole, allowing the probe body to be limited in the cavity.

20. The detecting device according to claim 15, wherein a cross sectional dimension of the probe head is matched to a cross sectional dimension of the through hole.
